(19) United States
(12) Patent Application Publication
(10) Pub. No.: US 2026/0164682 A1
(43) Pub. Date: Jun. 11, 2026

(54) METAL-OXIDE-SILICON (MOS) VARACTOR AND METHOD OF FORMING

(71) Applicant: Microchip Technology Incorporated, Chandler, AZ (US)

(72) Inventor: Yaojian Leng, Vancouver, WA (US)

(73) Assignee: Microchip Technology Incorporated, Chandler, AZ (US)

(21) Appl. No.: 19/039,294

(22) Filed: Jan. 28, 2025

Related U.S. Application Data
(60) Provisional application No. 63/730,374, filed on Dec. 10, 2024.

(51) Int. Cl. H10D 1/64; H10D 1/00; H10D 84/00

(52) U.S. Cl. CPC H10D 1/64; H10D 1/045; H10D 84/215

(57) ABSTRACT

An integrated circuit apparatus includes a transistor and a varactor. The transistor includes a transistor source and a transistor drain formed in a transistor well area of a semiconductor substrate, a transistor gate oxide formed over the substrate, and a transistor gate formed over the transistor gate oxide. The varactor is located laterally offset from the transistor and includes a pair of varactor source/drain regions formed in a varactor well area of the semiconductor substrate, a varactor gate insulator formed over the substrate, and a varactor gate formed over the varactor gate insulator, wherein the varactor gate is formed from a different material than the transistor gate.

### RELATED APPLICATION

This application claims priority to commonly owned U.S. Provisional Patent Application No. 63/730,374 filed Dec. 10, 2024, the entire contents of which are hereby incorporated by reference for all purposes.

### TECHNICAL FIELD

The present disclosure relates to a metal-oxide-silicon (MOS) varactor and methods of forming an MOS varactor.

### BACKGROUND

A Metal-Oxide-Silicon (MOS) Varactor is a capacitor having a capacitance value that changes as a function of an applied voltage. MOS Varactors have wide range of applications, for example including (a) changing the frequency of a Voltage-Controlled Oscillator (VCO), (b) tuning the frequency characteristics of high frequency filters, (c) use with adaptive equalizers (e.g., wherein the varactor uses the equalizer feedback signal), (d) tuning radio receivers and transmitters, and (e) adjusting time constants of fast switching circuits.

An MOS varactor may be constructed simultaneously with complementary metal-oxide semiconductor (CMOS) transistors in a conventional CMOS process. A typical MOS varactor may have a similar structure as a CMOS transistor, except (a) the source/drain of the MOS varactor has the same dopant type as the well in which it is formed (e.g., n+ dopant for n-well, or p+ dopant for p-well) and (b) the source and drain are connected together at the same potential.

However, in a conventional device, the gate insulator of the MOS varactor is formed from the same material and with the same thickness as the gate oxide layer of neighboring CMOS transistors. In addition, the gate of the MOS varactor (also referred to as an electrode) is typically formed from the same material (e.g., polysilicon) as the CMOS transistor gates. These constraints may be disadvantageous. For example, depending on the relevant application, it may be advantageous to provide a varactor having a gate insulator formed from a different material and/or with a different thickness than the transistor gate oxide. For example, a thicker varactor gate insulator may provide wider control voltage range or larger signal swings with less distortion, while a thinner varactor gate insulator may provide a higher capacitance value, which may provide increased accuracy. As another example, forming the varactor gate insulator from a different material than the transistor gate oxide (e.g., including materials with a higher K value) may allow improved performance of the varactor. For instance, a varactor gate formed from metal (e.g., instead of the polysilicon gate of a conventional MOST varactor) may provide lower resistance and thus improved quality factor (Q factor), for example for varactors used in LC tanks.

There is a need for an MOS varactor with (a) a varactor gate insulator formed from a different material and/or with a different thickness than the gate oxide of neighboring CMOS transistors, and/or (b) a varactor gate formed from a different material (e.g., metal) and/or with a different thickness than the gates of neighboring CMOS transistors (commonly formed from polysilicon).

### SUMMARY

The present disclosure provides an improved MOS varactor and method of forming an improved MOS varactor. Some examples provide a MOS varactor with (a) a varactor gate insulator formed from a different material and/or with a different thickness than a gate oxide of neighboring transistor(s), and/or (b) a varactor gate formed from a different material (e.g., a metal varactor gate) and/or with a different thickness than the gate of neighboring transistor(s), (e.g., polysilicon transistor gates).

In some examples, a MOS varactor may be constructed concurrently with CMOS transistors, with no masks added to the background fabrication process. One or more characteristics of the varactor, for example (a) the material and/or thickness of the varactor gate insulator and/or (b) the material and/or thickness of the varactor gate, may be selected independent of the corresponding CMOS transistor materials and dimensions.

In addition, in some examples the MOS varactor may be constructed with different silicon dopant characteristics then CMOS transistors formed in the same substrate (e.g., silicon), as compared with conventional MOS varactors having the same fixed well implant of CMOS transistors formed on the same substrate.

One aspect provides an integrated circuit device, comprising a transistor and a varactor laterally offset from the transistor. The transistor includes a transistor source and a transistor drain formed in a transistor well area of a semiconductor substrate, a transistor gate oxide formed over the substrate, and a transistor gate formed over the transistor gate oxide. The varactor includes a pair of varactor source/drain regions formed in a varactor well area of the semiconductor substrate, a varactor gate insulator formed over the substrate, and a varactor gate formed over the varactor gate insulator, wherein the varactor gate is formed from a different material than the transistor gate.

In some examples, the transistor gate is formed from polysilicon and the varactor gate is formed from metal.

In some examples, the varactor gate insulator is formed from a different material than the transistor gate oxide.

In some examples, the varactor gate insulator has a vertical thickness different than a vertical thickness of the transistor gate oxide.

In some examples, the varactor gate insulator has a cup shape including a laterally extending bottom and vertical sidewalls extending upwardly from the laterally extending bottom, and the varactor gate is formed in an opening defined by the cup-shaped varactor gate insulator.

In some examples, the varactor gate has a different vertical thickness than the transistor gate.

In some examples, the varactor gate has a greater vertical thickness than the transistor gate.

In some examples, the IC device comprises a transistor gate pad and a varactor gate pad formed in a first metal layer, wherein the transistor gate pad is connected to the varactor gate by a vertically-extending gate contact, and wherein the varactor gate pad is formed directly on the varactor gate.

In some examples, the varactor well area is doped differently than the transistor well area.

One aspect provides a method of forming a varactor, including forming a pair of varactor source/drain regions in a varactor well area of a semiconductor substrate; forming a dielectric region over the semiconductor substrate; performing a first etch to form a tub opening and a pair of varactor source/drain contact openings in the dielectric region; depositing a contact metal over the dielectric region and extending into the tub opening and into the pair of varactor source/drain contact openings; performing a second etch to remove the contact metal in the tub opening; depositing a varactor gate insulator layer over the dielectric region and extending down into the tub opening; depositing a varactor gate metal layer over the varactor gate insulator layer and extending down into the tub opening; and performing a planarization process to remove upper portions of the varactor gate metal layer and upper portions of the varactor gate insulator layer; wherein after the planarization process, a remaining portion of the varactor gate insulator layer defines a cup-shaped varactor gate insulator, a remaining portion of the varactor gate metal layer defines a varactor gate in an opening defined by the cup-shaped varactor gate insulator, and remaining portions of the contact metal in the pair of varactor source/drain contact openings defines a pair of varactor source/drain contacts.

In some examples, the method includes, prior to forming the Pre-Metal Dielectric (PMD) region over the semiconductor substrate: forming a transistor source and a transistor drain in a transistor well area of the semiconductor substrate located laterally spaced apart from the varactor well area; forming a transistor gate oxide over the transistor well area of the semiconductor substrate; and forming a transistor gate over the transistor gate oxide; wherein the first etch also forms (a) a gate contact opening over the transistor gate, (b) a transistor source contact opening over the transistor source, and (c) a transistor drain contact opening over the transistor drain; wherein the deposited contact metal extends into the gate contact opening, the transistor source contact opening, and the transistor drain contact opening; and wherein after the planarization process, a remaining portion of the contact metal in the gate contact opening defines a gate contact, a remaining portion of the contact metal in the transistor source contact opening defines a transistor source contact, and a remaining portion of the contact metal in the transistor drain contact opening defines a transistor drain contact.

In some examples, the method includes, after the planarization process, forming a metal layer including a transistor gate pad conductively contacting the transistor gate contact, a transistor source pad conductively contacting the transistor source contact, a transistor drain pad conductively contacting the transistor drain contact, a varactor gate pad conductively contacting the varactor gate, and a pair of varactor source/drain pads conductively contacting the pair of varactor source/drain contacts, respectively.

In some examples, the transistor gate is formed from polysilicon and the varactor gate is formed from the varactor gate metal layer.

In some examples, the varactor gate insulator layer comprises a different material than the transistor gate oxide.

In some examples, the varactor gate insulator layer has a vertical thickness different than a vertical thickness of the transistor gate oxide.

In some examples, the varactor gate has a different vertical thickness than the transistor gate.

In some examples, the varactor gate has a greater vertical thickness than the transistor gate.

In some examples, the method includes, after the second etch to remove the contact metal in the tub opening, performing a dopant implant through the tub opening and into the varactor well area of the semiconductor substrate.

In some examples, the second etch to remove the contact metal in the tub opening comprises an isotropic etch.

One aspect provides a method of forming an integrated circuit device, including forming (a) a pair of transistor source/drain regions in a transistor well area of a semiconductor substrate and (b) a pair of varactor source/drain regions in a varactor well area of the semiconductor substrate; forming a transistor gate oxide over the transistor well area; forming a transistor gate over the transistor gate oxide; forming a Pre-Metal Dielectric (PMD) region over the semiconductor substrate and over the transistor gate; etching the dielectric region to form a tub opening over the varactor well area, and a pair of varactor source/drain contact openings over the pair of varactor source/drain regions, respectively; depositing a contact metal over the dielectric region and extending into the tub opening and into the pair of varactor source/drain contact openings; performing an etch to remove the contact metal from the tub opening; depositing a varactor gate insulator layer over the dielectric region and extending down into the tub opening; depositing a varactor gate metal layer over the varactor gate insulator layer and extending down into the tub opening; and performing a planarization process to remove upper portions of the varactor gate metal layer and upper portions of the varactor gate insulator layer; wherein after the planarization process, a remaining portion of the varactor gate insulator layer defines a cup-shaped varactor gate insulator, a remaining portion of the varactor gate metal layer defines a varactor gate in an opening defined by the cup-shaped varactor gate insulator, and remaining portions of the contact metal in the pair of varactor source/drain contact openings defines a pair of varactor source/drain contacts.

### BRIEF DESCRIPTION OF THE DRAWINGS

Example aspects of the present disclosure are described below in conjunction with the figures, in which:

FIG. 1 shows a cross-sectional side view of an example integrated circuit (IC) device including a transistor (e.g., a CMOS transistor) and a varactor (e.g., a MOS varactor) formed on a common semiconductor substate;

FIGS. 2A-21 are a series of cross-sectional side views showing an example process for forming the example IC device shown in FIG. 1;

FIG. 3 shows an example IC device including a transistor and a varactor and including contact pads formed in a metal-1 layer formed by a copper damascene process; and

FIG. 4 is a flowchart of an example method for forming an IC device including a transistor and a varactor.

It should be understood that the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

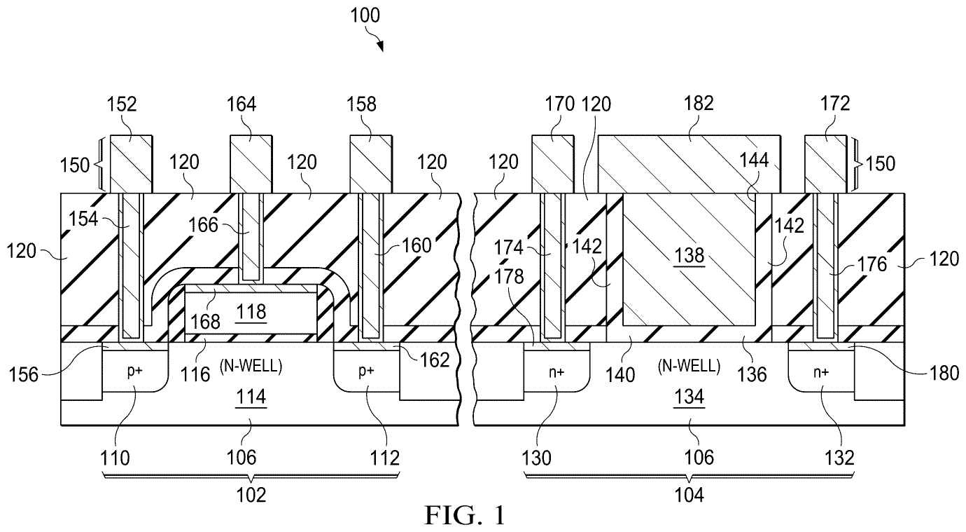

FIG. 1 shows a cross-sectional side view of an example integrated circuit (IC) device 100 including a transistor 102 (e.g., a CMOS transistor) and a varactor 104 (e.g., a MOS varactor) formed laterally offset from each other on a common semiconductor substate 106 (e.g., silicon substrate). The transistor 102 includes a source 110 and a drain 112 formed in a transistor well area 114 of the semiconductor substrate 106, a transistor gate oxide 116 formed over the substrate, and a transistor gate 118 formed over the transistor gate oxide 116 in a dielectric region 120, in this example a Pre-Metal Dielectric (PMD) layer.

The varactor 104 includes a pair of source/drain regions 130 and 132 formed in a varactor well area 134 of the semiconductor substrate 106, a varactor gate insulator 136 formed over the substrate laterally between the source/drain regions 130 and 132, and a varactor gate 138 formed over the varactor gate insulator 136 in the dielectric region 120.

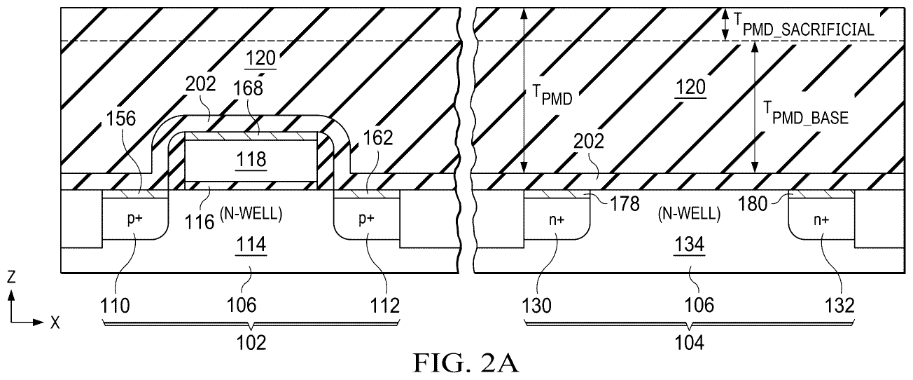

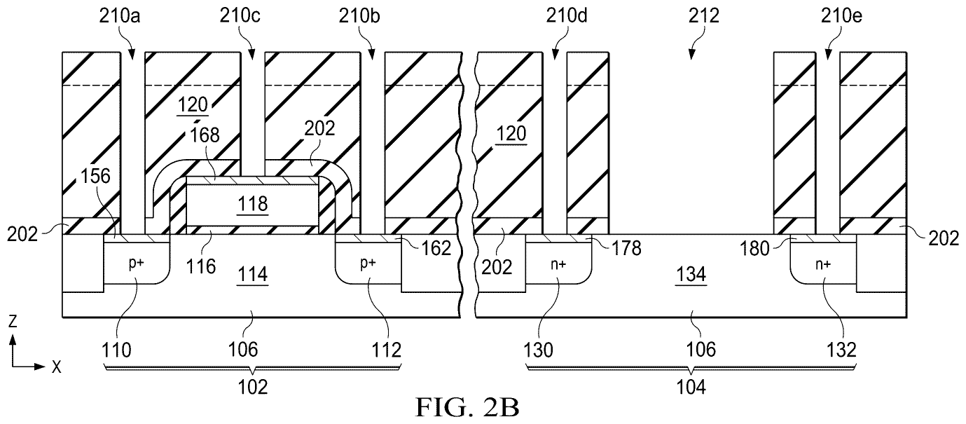

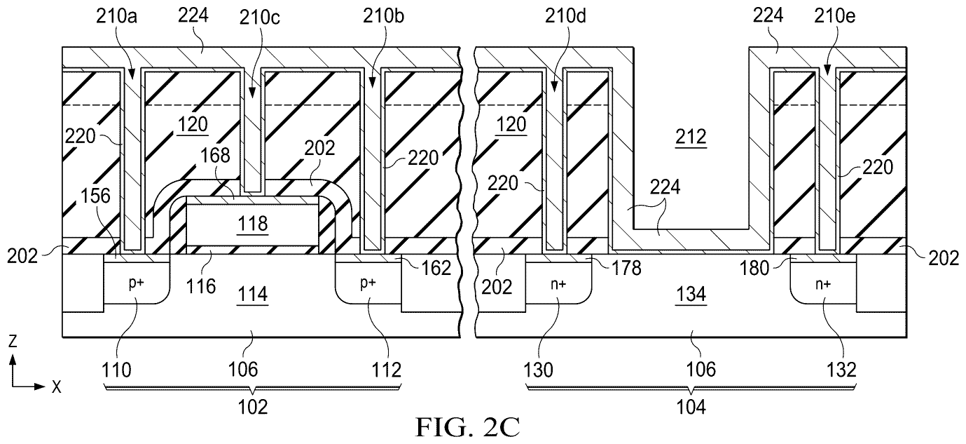

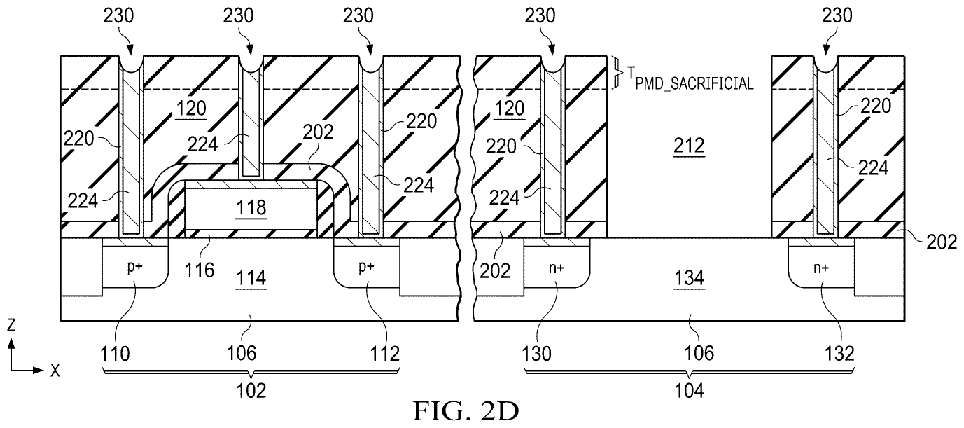

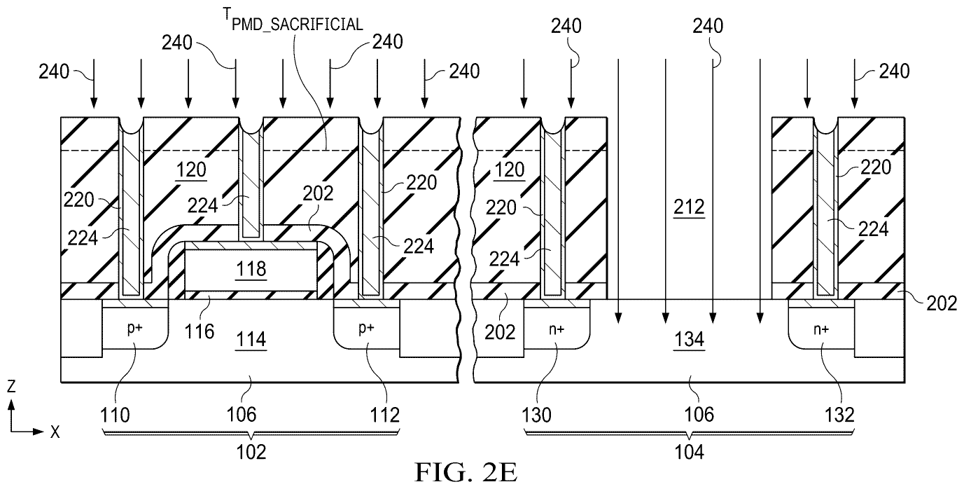

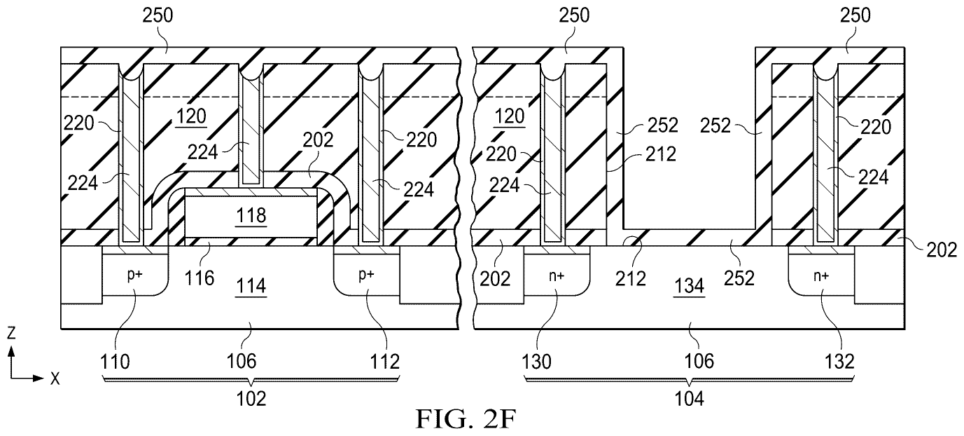

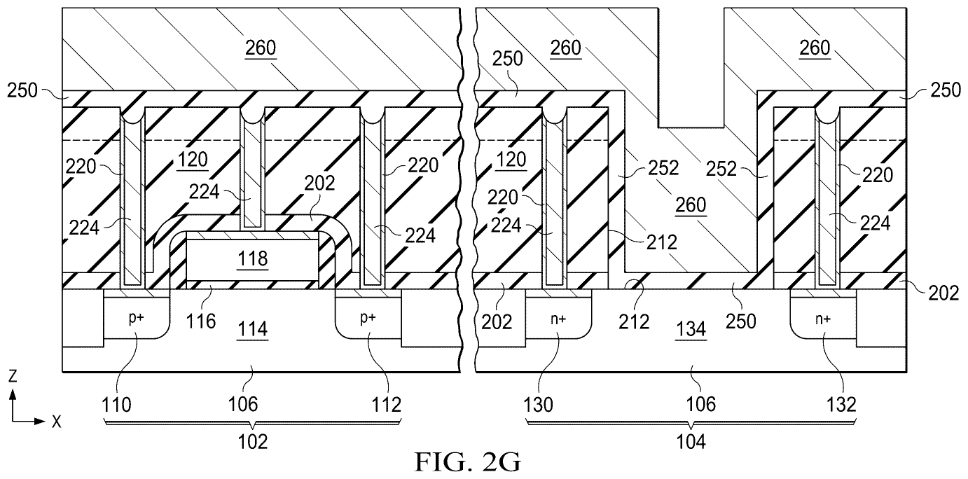

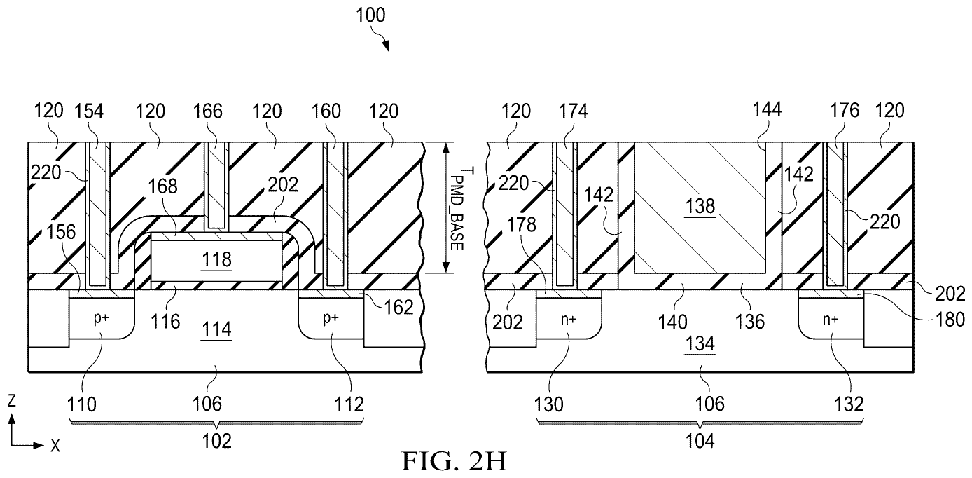

The transistor source 110 and drain 112 are doped with the opposite type of dopant than the transistor well 114 (e.g., p+ doped source 110 and drain 112 formed in an n-well 114), while the varactor source 130 and drain 132 are typically doped with the same type of dopant as the varactor well 134 (e.g., n+ doped source 130 and drain 132 formed in an n-well 134). In addition, the varactor well 134 may be doped differently (independently) than the transistor well 114, for example by performing an implant into the varactor well 134 but not the transistor well 114 to improve the performance of varactor 104, e.g., as shown in FIG. 2E and discussed below.

In some examples, the varactor gate 138 may be formed from a different material than the transistor gate 118. For example, the transistor gate 118 may be formed from polysilicon, while the varactor gate 138 may be formed from metal, for example titanium nitride (TiN), tungsten (W), aluminum (Al), tantalum (Ta), tantalum nitride (TaN), titanium (Ti), or a combination thereof, e.g., TiN+W, or TiN+Al. A metal varactor gate 138 may provide low resistance, and thus a higher quality factor (Q factor), e.g., as compared with poly gate.

Further, the varactor gate 138 may have a different vertical (z-direction) height or thickness than the transistor gate 118. In the example shown in FIG. 1, the varactor gate 138 has a greater vertical height (extending up to the metal-1 layer 150 discussed below) than the transistor gate 118.

Further, in some examples, the varactor gate insulator 136 may be formed from a different material than the transistor gate oxide 116 and/or may have a different thickness T_{VAR_INS} than a thickness T_{TRANS_OXIDE} of the transistor gate oxide 116, e.g., to provide desired performance characteristics of the varactor 104 for the respective application of device 100. For example, in some examples the transistor gate oxide 116 may be formed from silicon dioxide (SiO₂), while the varactor gate insulator 136 may be formed from silicon oxide nitride (SiOₓN_{y} or other accepted formula), silicon nitride (Si₃N₄), or other high K gate dielectric (e.g., HfO₂, CeHfO₂, Er—HfO₂, HfTiON, or HfSiO₂).

As another example, the thickness T_{VAR_INS} of the varactor gate insulator 136 may be less than or greater than the thickness T_{TRANS_OXIDE} of the transistor gate oxide 116. As one example only, the transistor gate oxide thickness T_{TRANS_OXIDE} may have a value of 70-150 Å for a 5V CMOS device, while the varactor gate insulator T_{VAR_INS} may have a value of 400-600 Å for a silicon nitride layer, e.g., suitable for a 15V varactor.

In some examples, the varactor gate insulator 136 has a cup shape including a laterally extending bottom 140 and vertical sidewalls 142 extending upwardly from the laterally extending bottom 140, and the varactor gate 138 is formed in an opening 144 defined by the cup-shaped varactor gate insulator 136.

The transistor 102 and a varactor 104 are connected to respective electrical connections. In the illustrated example, transistor 102 and varactor 104 are connected to respective contact pads formed in a metal layer 150 formed over the PMD region 120, referred to as the metal-1 or M1 layer. As shown in FIG. 2, a source pad 152 is conductively connected to the transistor source 110 by a source contact 154 in contact with a silicide layer 156 formed on the source 110, a drain pad 158 is conductively connected to the transistor drain 112 by a drain contact 160 in contact with a silicide layer 162 formed on the drain 112, and a gate pad 164 is conductively connected to the transistor gate 118 by a gate contact 166 in contact with a gate silicide layer 168 formed on the gate 118.

In addition, a pair of source/drain pads 170, 172 are respectively conductively connected to the varactor source/drain regions 130, 132 by source/drain contacts 174, 176 in contact with silicide layers 178, 180 formed on the varactor source/drain regions 130, 132, respectively, and a varactor gate pad 182 is formed directly on the varactor gate 138.

FIGS. 2A-21 are a series of cross-sectional side views showing an example process for forming the example IC device 100 shown in FIG. 1, with like reference numbers referring to like parts.

As shown in FIG. 2A, the transistor 102 is formed over the semiconductor substrate 106, including forming the doped source 110 and drain 112 in the transistor well 114, forming silicide layers 156 and 162 thereon, and forming the gate oxide 116, gate 118, and gate silicide layer 168. In addition, the varactor source 130 and drain 132 are formed (implanted) in the varactor well 134, for example an n+ doped source 130 and drain 132 in an n-well 134.

An optional contact etch stop layer 202 (e.g., a silicon nitride (SiN) layer deposited by Plasma Enhanced Chemical Vapor Deposition (PECVD) to a thickness of about 500 Å) may be formed over the semiconductor substrate 106 and transistor gate 118. The PMD region 120, e.g., comprising silicon dioxide (SiO₂), is formed over the contact etch stop layer 202 (e.g., by PECVD) and planarized (e.g., by chemical mechanical planarization (CMP)) to a total thickness T_{PMD} including (a) a base thickness T_{PMD_BASE} corresponding with the final thickness of the PMD region 120 after the fabrication process (i.e., the final structure shown in FIG. 1) and (b) a sacrificial thickness T_{PMD_SACRIFICIAL} provided to account for the etched recesses formed in the top of each metal contact structure as discussed below with reference to FIG. 2D. In some examples, the base thickness T_{PMD_BASE} and sacrificial thickness T_{PMD_SACRIFICIAL} comprise respective portions of a continuous region of dielectric material, e.g., SiO₂.

In some examples, the base thickness T_{PMD_BASE} comprises a first dielectric material and the sacrificial thickness T_{PMD}_SACRIFICIAL comprises a second, different dielectric material deposited over the first dielectric material.

As shown in FIG. 2B, contact openings 210a-210e and a varactor gate tub opening 212 are patterned and etched in the PMD region 120, e.g., using known photolithography processes. The contact openings 210a-210e include a transistor source contact opening 210a, a transistor drain contact opening 210b, a transistor gate contact opening 210c, and a pair of varactor source/drain contact openings 210d and 210e. In some examples, respective contact openings 210a-210e may have a critical dimension (CD) (x-direction and y-direction) in the range of 0.1-0.5 μm, while the varactor gate tub opening 212 may have a dimension (x-direction and y-dimension) in the range of 1-100 μm. If present, the optional contact etch stop layer 202 may be used to control the depth of contact etch, e.g., to avoid overetch through the transistor gate 118.

As shown in FIG. 2C, a liner layer 220 (e.g., comprising titanium nitride (TiN)) may be deposited, followed by deposition of a conformal contact metal 224 (e.g., tungsten), e.g., by chemical vapor deposition (CVD), which conformal contact metal 224 extends down into the contact openings 210a-210e and into the varactor gate tub opening 212. As shown, the conformal contact metal 224 may fully fill the contact openings 210a-210e and partially fill the varactor gate tub opening 212.

As shown in FIG. 2D, a contact metal etch is performed to remove the contact metal 224 from the varactor gate tub opening 212. The contact metal etch may be a wet or dry (plasma) etch, and may be isotropic to fully remove the contact metal 224 from the varactor gate tub opening 212. As shown, the etch removes the contact metal 224 on top of the PMD region 120, and may form a recess 230 in the remaining contact metal 224 in each of the contact openings 210a-210c. In some examples, the recesses 230 do not extend below the sacrificial PMD thickness T_{PMD_SACRIFICIAL}.

As shown in FIG. 2E, an optional additional ion implant may be performed, as indicated by arrows 240, to improve or optimize the dopant profile of the varactor well 134 to improve the performance of the varactor 104. Depending on the example implementation, the implant angles can be straight or tilted, or a combination thereof. In addition, the implant species may be the same as the varactor well 134 (e.g., to improve contact and enhance the Q factor) or different from the varactor well 134 (e.g., to create an isolation well to separate the varactor well 134 from the surrounding semiconductor substrate 106, e.g., to reduce noise). In some examples, the sacrificial PMD thickness T_{PMD_SACRIFICIAL} may act as an implant block layer to protect the transistor 102, such that no additional photo mask layer is needed.

As shown in FIG. 2F, a varactor gate insulation layer 250 is deposited over the structure and extending down into the varactor gate tub opening 212 to define a cup-shaped varactor gate insulator structure 252 in the varactor gate tub opening 212. In some examples the varactor gate insulation layer 250 may be deposited by rapid thermal process (RTP). The varactor gate insulation layer 250 may comprise oxide or other material, for example silicon oxide nitride (SiOₓN_{y}), silicon nitride (Si₃N₄), or other high K gate dielectric (e.g., HfO₂, CeHfO₂, Er—HfO₂, HfTION, or HfSiO₂). The thickness of the varactor gate insulation layer 250 may be selected based on device performance requirements.

As shown in FIG. 2G, a varactor gate metal layer 260 is deposited over the varactor gate insulator layer 250 and extending down into the varactor gate tub opening 212. In some examples the varactor gate metal layer 260 may be deposited by physical vapor deposition (PVD), and may comprise TiN, W, Al, TaN, Ta, Ti, or a combination thereof, e.g., TiN+W, or TiN+Al.

As shown in FIG. 2H, a planarization process (e.g., a CMP process) is performed to remove upper portions of the varactor gate metal layer 260, upper portions of the varactor gate insulator layer 250, and the sacrificial PMD thickness T_{PMD_SACRIFICIAL} of the PMD region 120, leaving the base PMD thickness T_{PMD_BASE}. After the planarization process, (a) remaining portions of the contact metal 224 in the transistor source and drain contact openings 210a and 210b define the transistor source and drain contacts 154 and 160 in contact with the silicide layers 156 and 162 formed on the transistor source and drain regions 110 and 112, respectively, (b) a remaining portion of the contact metal 224 in the transistor gate contact opening 210c defines the transistor gate contact 166 in contact with the gate silicide layer 168 formed on the transistor gate 118 (e.g., poly gate), (c) remaining portions of the contact metal 224 in the varactor source/drain contact openings 210d and 210e define the varactor source/drain contacts 174 and 176 in contact with the silicide layers 178 and 180 formed on the varactor source/drain regions 130 and 132, respectively, (c) a remaining portion of the cup-shaped varactor gate insulator structure 252 defines the cup-shaped varactor gate insulator 136, and (f) a remaining portion of the varactor gate metal layer 260 defines the varactor gate 138 in the opening 144 defined by the cup-shaped varactor gate insulator 136.

As shown in FIG. 2I, the metal layer 150 (e.g., Metal-1 or M1 layer) may be formed over the PMD region 120, e.g., by a deposition and etch process or a damascene process. The metal layer 150 may include various metal structures including the source pad 152 connected to the source contact 154, the drain pad 158 connected to the transistor drain 112, the gate pad 164 connected to the transistor gate 118, the source/drain pads 170, 172 connected to the varactor source/drain contacts 174, 176, and the varactor gate pad 182 formed directly on the varactor gate 138. In some examples, metal layer 150 may comprise interconnect elements formed by deposition of a metal layer (e.g., aluminum), and patterning and etching the metal layer.

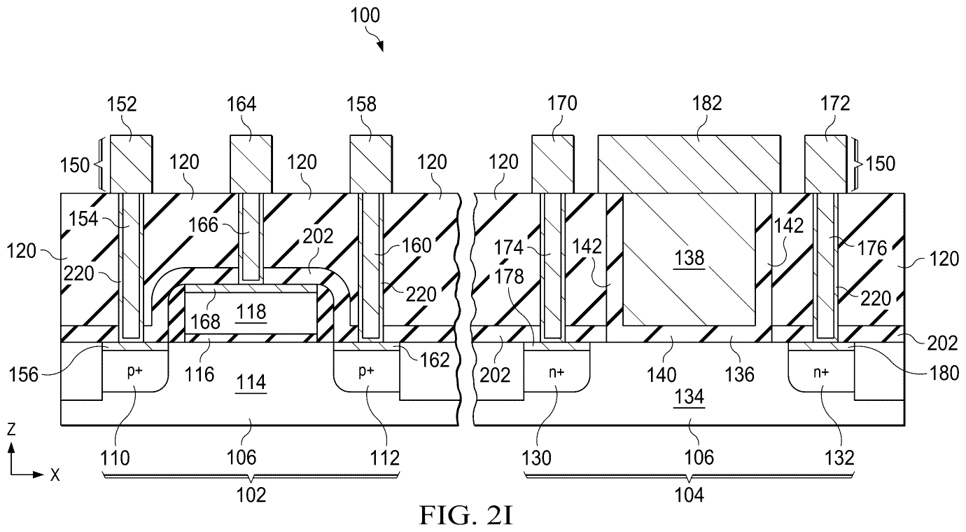

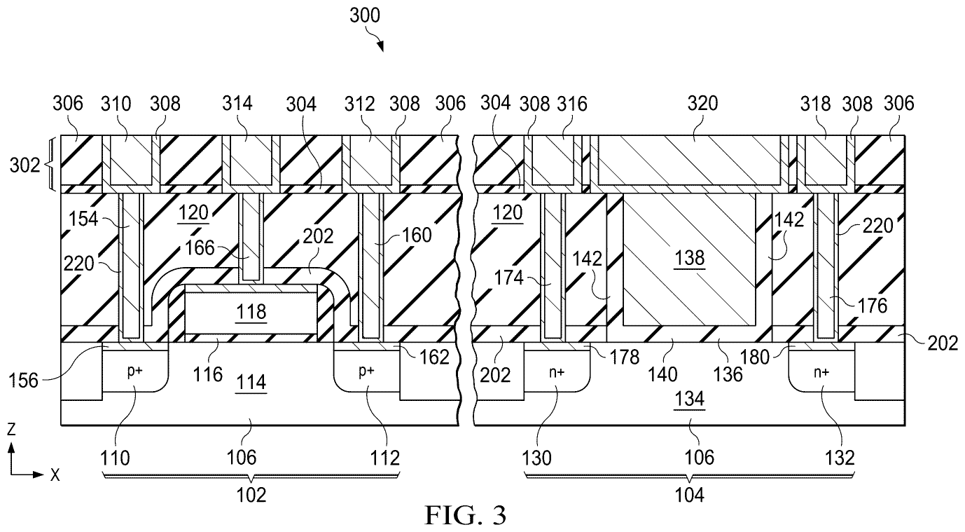

In some examples, metal layer 150 may be formed by a damascene process, e.g., for forming copper interconnect. FIG. 3 shows an example IC device 300 similar to the example IC device 100 shown in FIG. 1 and FIG. 2I, but including a metal layer 302 (e.g., Metal-1 or M1 layer) formed by a copper damascene process. As shown, a trench etch stop layer 304 (e.g., an SiN layer having a thickness of about 500 Å) is deposited on the PMD region 120, followed by deposition of an inter-metal dielectric (IMD1) layer 306 (e.g., oxide, fluorosilicate glass (FSG), organosilicate glass (OSG), or porous OSG, deposited by PECVD). A trench pattern and etch may be performed in the IMD1 layer 306, followed by deposition of a metal barrier layer (e.g., Ta/TaN bilayer) 308, copper seed deposition and copper plating of in the etched trenches, followed by a copper anneal and copper CMP process, to form a copper transistor source pad 310, transistor drain pad 312, transistor gate 314, varactor source/drain pads 316, 318, and varactor gate pad 320.

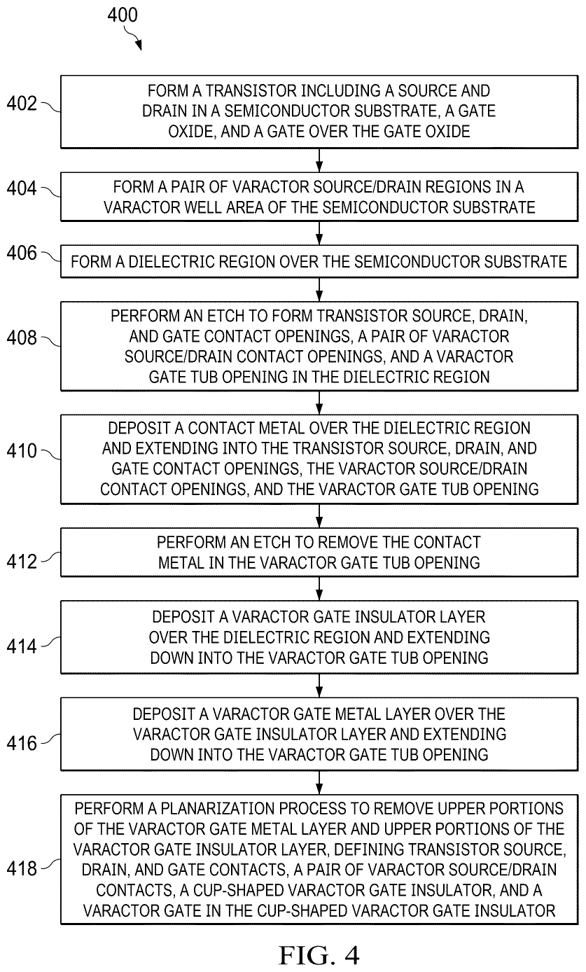

FIG. 4 is a flowchart of an example method 400 for forming an IC device including a transistor and a varactor, e.g., the example IC device 100 or 300 discussed above. At 402, a transistor is formed, including forming a transistor source and drain in a transistor well area of a semiconductor substrate, forming a gate oxide over the transistor well area, and forming a gate over the transistor gate oxide. At 404, at some point during the formation of the transistor at 402, a pair of varactor source/drain regions are formed in a varactor well area of the semiconductor substrate located laterally spaced apart from the transistor well area.

At 406, a dielectric region is formed over the semiconductor substrate and over the transistor gate. At 408, an etch is performed to form a transistor source contact opening, a transistor drain contact opening, a transistor gate contact opening, a pair of varactor source/drain contact openings, and a varactor gate tub opening in the dielectric region.

At 410, a contact metal is deposited over the dielectric region and extending into the transistor source contact opening, transistor drain contact opening, transistor gate contact opening, the pair of varactor source/drain contact openings, and the varactor gate tub opening.

At 412, an etch is performed to remove the contact metal in the tub opening. At 414, a varactor gate insulator layer is deposited over the dielectric region and extending down into the varactor gate tub opening. At 416, a varactor gate metal layer is deposited over the varactor gate insulator layer and extending down into the varactor gate tub opening.

At 418, a planarization process is performed to remove upper portions of the varactor gate metal layer and upper portions of the varactor gate insulator layer. After the planarization process, a remaining portion of the contact metal in the gate contact opening defines a gate contact, a remaining portion of the contact metal in the transistor source contact opening defines a transistor source contact, a remaining portion of the contact metal in the transistor drain contact opening defines a transistor drain contact, remaining portions of the contact metal in the pair of varactor source/drain contact openings defines a pair of varactor source/drain contacts, a remaining portion of the varactor gate insulator layer defines a cup-shaped varactor gate insulator, and a remaining portion of the varactor gate metal layer defines a varactor gate in an opening defined by the cup-shaped varactor gate insulator.

Although example embodiments have been described above, other variations and embodiments may be made from this disclosure without departing from the spirit and scope of these embodiments.

1. An integrated circuit device, comprising:
a transistor comprising:
a transistor source and a transistor drain formed in a transistor well area of a semiconductor substrate;
a transistor gate oxide formed over the substrate; and
a transistor gate formed over the transistor gate oxide; and
a varactor laterally offset from the transistor, the varactor comprising:
a pair of varactor source/drain regions formed in a varactor well area of the semiconductor substrate;
a varactor gate insulator formed over the substrate; and
a varactor gate formed over the varactor gate insulator, wherein the varactor gate is formed from a different material than the transistor gate.

2. The integrated circuit device of claim 1, wherein the transistor gate is formed from polysilicon and the varactor gate is formed from metal.

3. The integrated circuit device of claim 1, wherein the varactor gate insulator is formed from a different material than the transistor gate oxide.

4. The integrated circuit device of claim 1, wherein the varactor gate insulator has a vertical thickness different than a vertical thickness of the transistor gate oxide.

5. The integrated circuit device of claim 1, wherein:
the varactor gate insulator is cup-shaped including a laterally extending bottom and vertical sidewalls extending upwardly from the laterally extending bottom; and
the varactor gate is formed in an opening defined by the cup-shaped varactor gate insulator.

6. The integrated circuit device of claim 1, wherein the varactor gate has a different vertical thickness than the transistor gate.

7. The integrated circuit device of claim 6, wherein the varactor gate has a greater vertical thickness than the transistor gate.

8. The integrated circuit device of claim 7, comprising a transistor gate pad and a varactor gate pad formed in a first metal layer;
wherein the transistor gate pad is connected to the varactor gate by a vertically-extending gate contact; and
wherein the varactor gate pad is formed directly on the varactor gate.

9. The integrated circuit device of claim 1, wherein the varactor well area is doped differently than the transistor well area.

10. A method of forming a varactor, comprising:
forming a pair of varactor source/drain regions in a varactor well area of a semiconductor substrate;
forming a dielectric region over the semiconductor substrate;
performing a first etch to form a tub opening and a pair of varactor source/drain contact openings in the dielectric region;
depositing a contact metal over the dielectric region and extending into the tub opening and into the pair of varactor source/drain contact openings;
performing a second etch to remove the contact metal in the tub opening;
depositing a varactor gate insulator layer over the dielectric region and extending down into the tub opening;
depositing a varactor gate metal layer over the varactor gate insulator layer and extending down into the tub opening; and
performing a planarization process to remove upper portions of the varactor gate metal layer and upper portions of the varactor gate insulator layer;
wherein after the planarization process, a remaining portion of the varactor gate insulator layer defines a cup-shaped varactor gate insulator, a remaining portion of the varactor gate metal layer defines a varactor gate in an opening defined by the cup-shaped varactor gate insulator, and remaining portions of the contact metal in the pair of varactor source/drain contact openings defines a pair of varactor source/drain contacts.

11. The method of claim 10, comprising:
prior to forming the dielectric region over the semiconductor substrate:
forming a transistor source and a transistor drain in a transistor well area of the semiconductor substrate located laterally spaced apart from the varactor well area;
forming a transistor gate oxide over the transistor well area of the semiconductor substrate; and
forming a transistor gate over the transistor gate oxide;
wherein the first etch also forms (a) a gate contact opening over the transistor gate, (b) a transistor source contact opening over the transistor source, and (c) a transistor drain contact opening over the transistor drain;
wherein the deposited contact metal extends into the gate contact opening, the transistor source contact opening, and the transistor drain contact opening; and
wherein after the planarization process, a remaining portion of the contact metal in the gate contact opening defines a gate contact, a remaining portion of the contact metal in the transistor source contact opening defines a transistor source contact, and a remaining portion of the contact metal in the transistor drain contact opening defines a transistor drain contact.

12. The method of claim 11, comprising, after the planarization process, forming a metal layer including:
a transistor gate pad conductively contacting the transistor gate contact;
a transistor source pad conductively contacting the transistor source contact;
a transistor drain pad conductively contacting the transistor drain contact;
a varactor gate pad conductively contacting the varactor gate; and
a pair of varactor source/drain pads conductively contacting the pair of varactor source/drain contacts, respectively.

13. The method of claim 11, wherein the transistor gate is formed from polysilicon and the varactor gate is formed from the varactor gate metal layer.

14. The method of claim 11, wherein the varactor gate insulator layer comprises a different material than the transistor gate oxide.

15. The method of claim 11, wherein the varactor gate insulator layer has a vertical thickness different than a vertical thickness of the transistor gate oxide.

16. The method of claim 11, wherein the varactor gate has a different vertical thickness than the transistor gate.

17. The method of claim 16, wherein the varactor gate has a greater vertical thickness than the transistor gate.

18. The method of claim 10, comprising, after the second etch to remove the contact metal in the tub opening, performing a dopant implant through the tub opening and into the varactor well area of the semiconductor substrate.

19. The method of claim 10, wherein the second etch to remove the contact metal in the tub opening comprises an isotropic etch.

20. A method of forming an integrated circuit device, comprising:
forming (a) a pair of transistor source/drain regions in a transistor well area of a semiconductor substrate and (b) a pair of varactor source/drain regions in a varactor well area of the semiconductor substrate;
forming a transistor gate oxide over the transistor well area;
forming a transistor gate over the transistor gate oxide;
forming a dielectric region over the semiconductor substrate and over the transistor gate;
etching the dielectric region to form a tub opening over the varactor well area, and a pair of varactor source/drain contact openings over the pair of varactor source/drain regions, respectively;
depositing a contact metal over the dielectric region and extending into the tub opening and into the pair of varactor source/drain contact openings;
performing an etch to remove the contact metal from the tub opening;
depositing a varactor gate insulator layer over the dielectric region and extending down into the tub opening;
depositing a varactor gate metal layer over the varactor gate insulator layer and extending down into the tub opening; and
performing a planarization process to remove upper portions of the varactor gate metal layer and upper portions of the varactor gate insulator layer;
wherein after the planarization process, a remaining portion of the varactor gate insulator layer defines a cup-shaped varactor gate insulator, a remaining portion of the varactor gate metal layer defines a varactor gate in an opening defined by the cup-shaped varactor gate insulator, and remaining portions of the contact metal in the pair of varactor source/drain contact openings defines a pair of varactor source/drain contacts.
